(19) United States
(12) Patent Application Publication
(10) Pub. No.: US 2005/0042548 A1
(43) Pub. Date: Feb. 24, 2005

(54) Self-aligned contact doping for organic field-effect transistors and method for fabricating the transistor

(76) Inventors: Hagen Klauk, Erlangen (DE); Guenter Schmid, Hemhofen (DE)

Correspondence Address: LERNER AND GREENBERG, PA, P O BOX 2480, HOLLYWOOD, FL, 33022-2480, US

(21) Appl. No.: 10/680,379

(22) Filed: Oct. 6, 2003

Related U.S. Application Data
(63) Continuation of application No. PCT/DE02/01191, filed on Apr. 3, 2002.

(30) Foreign Application Priority Data
Apr. 4, 2001 (DE) 101 16 876.4

(51) Int. Cl. G03F 7/00

(52) U.S. Cl. 430/311; 430/315; 430/319

(57) ABSTRACT

A method for doping electrically conductive organic compounds, fabricating organic field-effect transistors, and the transistor includes a dopant activated by radiation exposure, introduced into an electrically conductive organic compound, and exposed thereby, which triggers a chemical reaction to irreversibly fix the dopant in the organic compound. Such a transistor is significantly less expensive to fabricate than prior art organic field-effect transistors. Source and drain contacts and a gate electrode are next to one another on a substrate and a gate dielectric insulates the gate electrode. A distance, in which the organic semiconductor is applied directly to the substrate, is formed between gate dielectric and source or drain contact. Back-surface exposure enables production of doped regions in which the organic semiconductor has an increased electrical conductivity, while a low electrical conductivity of the organic semiconductor is retained in the channel region influenced by the field of the gate electrode.

### CROSS-REFERENCE TO RELATED APPLICATION

This application is a continuation of copending International Application No. PCT/DE02/01191, filed Apr. 3, 2002, which designated the United States and was not published in English.

### BACKGROUND OF THE INVENTION

1. Field of the Invention

The invention relates to a method for doping electrically conductive organic compounds, to a method for fabricating an organic field-effect transistor and to an organic field-effect transistor.

Field-effect transistors based on organic semiconductors are of interest for a wide range of electronic applications that require extremely low manufacturing costs, flexible or infrangible substrates, or the fabrication of transistors and integrated circuits over large active surface areas. By way of example, organic field-effect transistors are suitable as pixel control elements in active matrix displays. Such displays are, usually, fabricated with field-effect transistors based on amorphous or polycrystalline silicon layers. The temperatures of usually more than 250° C. that are necessary for the fabrication of high-quality transistors based on amorphous or polycrystalline silicon layers require the use of rigid and frangible glass or quartz substrates. On account of the relatively low temperatures at which transistors based on organic semiconductors are fabricated, usually of less than 100° C., organic transistors allow the fabrication of active matrix displays using inexpensive, flexible, transparent, infrangible polymer films that have considerable advantages over glass or quartz substrates.

A further application area for organic field-effect transistors is in the fabrication of highly inexpensive integrated circuits, as are used, for example, for the active marking and identification of goods and products. These so-called transponders are usually fabricated using integrated circuits based on single-crystal silicon, leading to considerable costs in terms of construction and connection. The fabrication of transponders based on organic transistors would lead to enormous reductions in costs and could help transponder technology towards a global breakthrough.

The fabrication of thin-film transistors usually requires four steps in which the various layers of the transistor are deposited. In a first step, the gate electrode is deposited on a substrate, then the gate dielectric is deposited on the gate electrode and, in a further step, the source and drain electrodes are deposited. In the final step, the semiconductor is deposited on the gate dielectric between the source electrode and the drain electrode.

H. Klauk, D. J. Gundlach, M. Bonse, C.-C. Kuo, and T. N. Jackson (Appl. Phys. Lett. 76, 1692-1694 (2000)) have proposed a simplified structure for an organic thin-film transistor, in which only three steps are required for deposition of the individual layers of the transistor. In this case, gate electrode and source and drain electrodes are deposited together on the substrate in a single step. Then, gate dielectric and the organic semiconductor are deposited. In such a structure, gate electrode and source or drain electrode no longer overlap so that regions that are no longer influenced by the field of the gate electrode are formed in the organic semiconductor. Therefore, the mobility and density of the charge carriers in these regions are relatively low and cannot be increased by the voltage that is present at the gate electrode. However, lengthening the conducting channel relative to the regions that are not influenced by the gate electrode does allow the properties of the thin-film transistor to be improved to a certain degree.

One of the main problems involved in the use of organic field-effect transistors is the relatively poor electrical properties of the source and drain contacts. Source and drain contacts are required to inject electrical charge carriers into the semiconductor layer at the source contact and to extract electrical charge carriers from the semiconductor layer at the drain contact so that an electric current can flow through the semiconductor layer from the source to the drain. The source and drain contacts of organic transistors are, generally, produced using inorganic metals or with the aid of conductive polymers to ensure that the electrical conductivity of the contacts is as high as possible.

The electrical properties of the source and drain contacts are often limited by the low electrical conductivity of the organic semiconductor material. Therefore, it is not the conductivity of the contacts themselves, but rather the conductivity of the semiconductor regions that adjoin the contacts and into which the charge carriers are injected or from which the charge carriers are extracted that represents the limiting factor. Most organic semiconductors that are suitable for use in organic field-effect transistors have very low electrical conductivities. By way of example, pentacene, which is often used for the fabrication of organic field-effect transistors, has a very low electrical conductivity of approximately 10⁻¹⁴ Ω⁻¹ cm⁻¹. If the organic semiconductor has a low electrical conductivity, the source and drain contacts often have very high contact resistances, which lead to a need for high electrical field strengths at the contacts in order for charge carriers to be injected and extracted. To improve the electrical properties of the source and drain contacts, i.e., to reduce the contact resistances, therefore, a high electrical conductivity of the organic semiconductor material is required in the regions that adjoin the contacts.

On the other hand, a high electrical conductivity of the organic semiconductor in the channel region has an adverse effect on the properties of the transistor. The channel region is the region of the field-effect transistor that is located between the source contact and the drain contact and the electrical conductivity of which is controlled by the electrical field applied to the gate electrode. A significant electrical conductivity in the charge carrier channel inevitably leads to high leakage currents, i.e., to relatively high electrical current intensities in the turned-off state. However, for many applications, low leakage currents in the region of 10⁻¹² A or lower are imperative. Moreover, a high electrical conductivity leads to the ratio between maximum turn-on current and minimum turn-off current being too low. Many applications require the maximum possible ratio between turn-on current and turn-off current in the region of 10⁷ or above because this ratio reflects the modulation behavior and the amplification behavior of the transistor.

Therefore, a low electrical conductivity of the semiconductor is required in the channel region, while a high electrical conductivity is necessary in the region of the source and drain contacts, in order to improve the contact properties.

During the fabrication of field-effect transistors based on amorphous or polycrystalline silicon layers, the contact regions are doped by the introduction of phosphorus or boron into the silicon layer in the vicinity of the source and drain contacts. The phosphorus or boron atoms are incorporated in the silicon network and act as charge donors or charge acceptors. As a result, the density of the free charge carriers and, therefore, the electrical conductivity of the silicon in the doped region are increased. The dopant is introduced into the silicon only in the region of the source and drain contacts, but not in the channel region. Because phosphorus and boron form covalent bonds with the silicon, there is no risk of these atoms diffusing into the channel region so that a low electrical conductivity in the charge carrier continues to be ensured.

The electrical conductivity of numerous organic semiconductors can, likewise, be increased by the introduction of suitable dopants. However, there are problems with producing positional selectivity during doping. In organic semiconductors, dopants are not limited to a specific position and can move freely inside the material. Even if the doping process can originally be limited to a certain region, such as, for example, the regions around the source and drain contacts, the dopants subsequently migrate through the entire organic semiconductor layer, in particular, under the influence of the electrical field that is applied between the source and drain contacts in order to operate the transistor. The diffusion of the dopant within the organic semiconductor layer inevitably increases the electrical conductivity in the channel region.

### SUMMARY OF THE INVENTION

The difficulties of positionally fixed doping are encountered as a general rule in electrically conductive organic compounds. It is accordingly an object of the invention to provide a self-aligned contact doping for organic field-effect transistors and method for fabricating the transistor that overcome the hereinafore-mentioned disadvantages of the heretofore-known devices and methods of this general type and that provides a method for doping electrically conductive organic compounds in which the doping is fixed in a positionally stable manner in the electrically conductive organic compound so that the dopant does not diffuse through the electrically conductive organic compound even under the influence of an electrical field.

With the foregoing and other objects in view, there is provided, in accordance with the invention, a method for doping electrically conductive organic compounds, includes the steps of introducing a doping substance activated by exposure with an activation radiation into an electrically conductive organic compound, irreversibly fixing the activatable doping substance in the organic compound as a result of exposing the organic compound with the activation radiation, and removing unbounded doping substance from the organic compound after the exposure.

A method for doping electrically conductive organic compounds, a method for fabricating organic field-effect transistors, and an organic field-effect transistor of simplified structure includes a dopant, which can be activated by exposure using activation radiation, introduced into an electrically conductive organic compound, and the electrically conductive organic compound is exposed using the activation radiation. The activation radiation triggers a chemical reaction, by which the dopant is irreversibly fixed in the electrically conductive organic compound. By using a suitable configuration of the individual elements of a transistor, it is possible to realize a transistor structure that is significantly less expensive to fabricate than organic field-effect transistors that have hitherto been known. In such a configuration, a source contact, a drain contact, and a gate electrode are disposed next to one another on a substrate. The gate electrode is insulated by a gate dielectric, the configuration being selected such that a distance, in which the organic semiconductor is applied directly to the substrate, is formed between gate dielectric and source or drain contact. Back-surface exposure makes it possible to produce doped regions in which the organic semiconductor has an increased electrical conductivity, while a low electrical conductivity of the organic semiconductor is retained in the channel region that has been influenced by the field of the gate electrode.

The incorporation of the dopant makes it possible to increase the conductivity of the electrically conductive organic compound. Because the dopant is fixed irreversibly in the electrically conductive organic compound, there are also no longer any difficulties caused by diffusion of the doping, for example, in an electrical field.

The electrically conductive organic compound is not per se subject to any restrictions. Suitable compounds that may be mentioned include polyenes, such as anthracene, tetracene or pentacene, polythiophenes or oligothiophenes, and their substituted derivatives, polypyrroles, poly-p-phenylenes, poly-p-phenylvinyl-idenes, naphthalenedicarboxylic dianhydrides, naphthalenebisimides, polynaphthalenes, phthalo-cyanines, copper phthalocyanines or zinc phthalo-cyananines and their substituted, in particular, fluorinated derivatives.

The activation radiation used may be any radiation that can convert the dopant into an activated state. By way of example, the exposure can be used to break a bond so as to form a free radical, the radical then reacting with the electrically conductive compound, forming a bond. The activation radiation generally has a wavelength of approximately 10⁻⁹ m to 10⁻⁵ m. It is possible to use monochromatic light or, preferably, polychromatic light. An example of a suitable light source for the activation radiation is a mercury high-pressure lamp that emits ultraviolet light.

The dopant is not inherently subject to any restrictions. In principle, all organic, inorganic and metal organic substances that allow the following reaction steps are suitable:
1. Reversible diffusion into the electrically conductive organic compound; and
2. Exposure with a suitable wavelength, if appropriate also at elevated temperature, which triggers a chemical reaction in the substance that has diffused in, as a result of which reaction the dopant is fixed in the electrically conductive organic compound.

The simplest form of the dopant is to use halogen compounds, such a chlorine, bromine, or iodine or their interhalogen compounds. These compounds dope the electrically conductive organic compound in its molecular form. Exposure using a suitable wavelength leads to photohalogenation of the electrically conductive organic compound. The bonding of the halogen to the semiconductor material is, in this case, covalent. As a result, subsequent diffusion is prevented. The halogens can be applied both from the solution and from the vapor phase.

In a similar manner, it is possible to use the highly volatile or gaseous compounds of boron (borane), phosphorus (phosphane, phosphines), arsenic, antimony, sulphur, germanium, and silicon, provided that they bear functional groups that are accessible for exposure but in the unexposed state do not spontaneously react with the organic semiconductor.

Metal carbonyl compounds, such as Ni(CO)₄, Fe(CO)₅, CO(CO)₆, Mo(CO)₆, Cr(CO)₆, are particularly suitable for the doping because they are photolabile and are converted into coordinatively unsaturated forms by the elimination of carbon monoxide. The coordinatively unsaturated forms are fixed by the usually aromatic, electrically conductive organic compound to form a coordinative bond. This fixing is irreversible in the preferred temperature range up to 300° C. The carbon monoxide that is eliminated photochemically diffuses out of the organic semiconductor layer. Besides the carbonyl complexes of the transition metals, their partially substituted derivatives are also suitable. Examples are compounds with phosphine, cyclopentadienyl ligands, cyclobutadienyl ligands or cyclooctatetraenyl ligands.

The range of metal organics that can be employed is not restricted to carbonyl complexes; in principle, all compounds that, when exposed, eliminate a highly volatile and readily diffusible compound and are, then, saturated by the formation of a coordinative bond with the electrically conductive organic compound, are suitable. Further examples of suitable compounds are Mo(N₂)₂(PH₃)₄ or Pd(R—C═C—R)₂, where R represents an organic radical. During exposure, these compounds release highly volatile compounds, such as N₂, P(CH₃)₃, P(C₂H₅)₃, C₂H₂, C₂H₄, cyclobutane, CO₂, H₂O, etc.

The advantages of this class of compounds are their high volatility or good solubility in solvents that are inert with respect to the electrically conductive organic compounds.

Examples of suitable inert solvents in which the dopants can be dissolved for diffusion into the electrically conductive organic compound include, inter alia, alkanes, such as pentane, hexane and heptane, aromatics, such as benzene, toluene or xylenes, alcohols, such as methanol, ethanol, or propanol, ketones, such as acetone, ethyl methyl ketone and cyclohexanone, esters, such as ethyl acetate or ethyl lactate, lactones, such as γ-butyrolactone, N-methylpyrrolidone, halogenated solvents, such as methylene chloride, chloroform, carbon tetrachloride, or chlorobenzene. It is also possible to use mixtures of the above-mentioned solvents.

The number of organic compounds that can be used as dopant is extraordinarily high. However, highly reactive compounds, such as the gaseous or readily vaporizable diazo compounds diazomethane and diazodichloromethane, are particularly suitable. When exposed, these compounds react spontaneously with the electrically conductive organic compound.

After the exposure, unbonded dopant is, preferably, removed again from the electrically conductive organic compound. Excess dopant may be removed, for example, at reduced pressure or elevated temperature. Particularly if the electrically conductive organic compound includes unexposed regions, after removal of the unreacted dopant the original electrical conductivity of the organic compound is restored in these regions.

A crucial point of the invention lies in the fact that the dopant is fixed irreversibly in the electrically conductive organic compound, i.e., can neither diffuse out of the electrically conductive organic compound nor migrate in an electrical field. The irreversible fixing of the dopant is, preferably, effected by forming a covalent bond and/or by forming a coordinative bond with the electrically conductive organic compound.

The method according to the invention is suitable particularly for the fabrication of organic electronic components, such as transistors or diodes. Therefore, the electrically conductive organic compound is, preferably, an organic semiconductor. The conductivity of the organic semiconductor can be varied within several powers of ten by the doping using the method according to the invention. An organic semiconductor is an organic compound whose electrical conductivity is greater than that of a typical insulator but lower than that of a typical metal. In particular, an organic semiconductor is distinguished by the fact that its electrical conductivity can be modulated over wide ranges, i.e., can be varied by the introduction of suitable dopants or by the action of electrical fields.

The method according to the invention is also suitable for the fabrication of large-area electronic circuit configurations, as are used, for example, to control active matrix displays.

To be able to produce regions of different electrical conductivity, the exposure of the electrically conductive organic compound is, preferably, carried out in sections. As a result, the electrical conductivity of the electrically conductive organic compound rises only in the exposed regions, while the original electrical conductivity is restored in the unexposed regions after removal of unreacted dopant.

The exposure in sections can be carried out, for example, using a photomask. It is possible to use standard methods that are known from the fabrication of semiconductor elements.

In accordance with another mode of the invention, light-impermeable regions, which are impermeable to the activation radiation used for the exposure, are provided in the electrically conductive organic compound. During the exposure, unexposed sections are retained in the electrically conductive compound, these sections being disposed behind the light-impermeable regions as seen in the direction from a radiation source used for the exposure towards the electrically conductive organic compounds. The light-impermeable regions shield the regions of the electrically conductive organic compound disposed on the side remote from the radiation source from the activation radiation so that, in these regions, there is no doping with the dopant and, therefore, no increase in the electrical conductivity either. Therefore, by suitably disposing the light-impermeable regions in the electrically conductive organic compound, it is possible to dispense with a photomask. As a result, considerable savings can be achieved during the fabrication of such organic electronic components. The light-impermeable regions may be formed, for example, by a gate electrode of a transistor.

In accordance with yet another feature of the invention, the light-opaque regions are formed by a gate electrode.

The method described above is, in principle, suitable for the fabrication of various types of organic electronic components. However, it is particularly suitable for the fabrication of organic field-effect transistors because these are composed of areas within various layers of a larger electronic component. The individual layers can very easily be selectively exposed in different sections.

Therefore, the invention also relates to a method for fabricating an organic field-effect transistor, in which a gate electrode, a source contact, a drain contact, a gate dielectric, and an organic semiconductor are deposited on a substrate, a dopant that can be activated by exposure using activation radiation is introduced into the organic semiconductor is exposed in sections using the activation radiation so that the dopant is fixed irreversibly in the organic semiconductor in regions of the organic semiconductor that adjoin the source contact and the drain contact, and contact regions of increased electrical conductivity, which adjoin the source contact and the drain contact, are obtained.

The organic field-effect transistor, therefore, has the standard structure, except that during fabrication a doping step is introduced, in which the electrical conductivity in the sections in which the charge carriers are subsequently to be transferred between the source or drain contact and the organic semiconductor, is increased. To achieve a selective increase in the electrical conductivity in certain sections of the organic semiconductor, known methods are used to apply a photomask to the organic semiconductor, and, then, the organic semiconductor is irradiated with a suitable activation length, e.g., UV radiation, so that the dopant is fixed irreversibly in the organic semiconductor. To do this, it is possible, for example, to use the dopants described above.

In accordance with a further mode of the invention, the individual elements of the field-effect transistor are disposed such that a photomask can be dispensed with. For such a purpose, a gate electrode as well as source and drain contacts that are at a distance from the gate electrode are deposited on a substrate that is transparent to the activation radiation. A gate dielectric is deposited on the gate electrode such that a distance over which the substrate is uncovered is maintained between the gate dielectric and the source contact and between the gate dielectric and the drain contact. Then, an organic semiconductor is deposited on the substrate, the source contact, the drain contact, and the gate dielectric, the distance between gate dielectric and source contact and/or the distance between gate dielectric and drain contact being filled by the organic semiconductor, a dopant that can be activated by exposure using the activation radiation being introduced into the organic semiconductor, and finally being exposed using the activation radiation from the side of the substrate so that contact regions of increased conductivity are obtained in the organic semiconductor adjacent to the source contact and to the drain contact. Finally, excess dopant is removed from the organic semiconductor.

The gate electrode, which is insulated by the gate dielectric, shields the activation radiation from those regions of the organic semiconductor that are disposed on the side remote from the illumination source. As a result, there is no irreversible doping of the organic semiconductor in these regions during the exposure. If, after the exposure, the dopant that is present in these regions is removed again, the organic semiconductor returns to its original, low electrical conductivity. These regions form the conducting channel or the channel region of the organic field-effect transistor, which is influenced by the field of the gate electrode. The conductivity of the organic semi-conductor is increased by several powers of ten in the exposed regions. As a result, the contact resistances that occur at the transitions between source electrode and organic semiconductor are reduced considerably so that the properties of the transistor are improved significantly.

In accordance with an added mode of the invention, it is preferable for gate electrode, source contact, and drain contact to be deposited simultaneously on the substrate. In such a case, gate electrode, source contact, and drain contact are of the same material, and they are deposited in a single working step, allowing further cost savings to be achieved.

In accordance with an additional mode of the invention, it is particularly preferable for the gate dielectric to be composed of a material that is transparent to the activation radiation. In such a case, during exposure from the back surface of the configuration, the regions of the organic semiconductor that are disposed above the gate dielectric outside the region shielded by the gate electrode, are also exposed and doped. The doped contact regions, then, seamlessly adjoin the region that is influenced by the field of the gate electrode. The choice of material used for the gate dielectric is dependent on the wavelength of the activation radiation, i.e., on the nature of the dopant and on the energy interplay between dopant and semiconductor. For example, silicon dioxide is transparent to wavelengths from the region of visible light and the near UV, but is not transparent to UV light with wavelengths of below approximately 350 nm.

As has already been explained, the use of a photomask can be avoided by suitable configuration of the elements of a transistor. Furthermore, source and drain contacts and gate electrodes can be disposed such that they can be deposited on the substrate in a common working step. As such, it is possible to use the methods described above to produce high-performance transistors that are inexpensive to fabricate.

With the objects of the invention in view, there is also provided an organic field-effect transistor, including a gate electrode, a gate dielectric insulating the gate electrode, a source contact, a drain contact, and an organic semiconductor being disposed between the source contact and the drain contact, adjoining at least one of the source contact and the drain contact, having a contact region with increased electrical conductivity, and being doped with a doping substance irreversibly fixed in the organic semiconductor.

In accordance with yet a further feature of the invention, the organic field-effect transistor can be fabricated at particularly low cost if the organic field-effect transistor has a front surface and a back surface and the back surface includes at least one section that is formed by the organic semiconductor. The section formed by the organic semiconductor can, then, be selectively exposed by exposing the back surface using a corresponding activation radiation. The exposed sections have an increased electrical conductivity on account of the irreversibly fixed dopant.

In accordance with yet an added feature of the invention, it is preferable for the back surface to include at least one section that is formed by the source contact or by the drain contact and that adjoins the section formed by the organic semiconductor. In such a case, the source contact and drain contact are disposed directly on the substrate, regions of the organic semiconductor that are disposed directly on the substrate likewise adjoining them. The section formed by the organic semiconductor is, preferably, doped with the irreversibly doped substance and, therefore, has an increased electrical conductivity, which facilitates the transfer of charge carriers between the contacts and the organic semiconductor. The dopant is, preferably, fixed irreversibly in the organic semiconductor by a covalent bond or a coordinative bond.

In accordance with a concomitant feature of the invention, when the organic field-effect transistor is viewed from above, there is no overlap between the gate electrode, source contact, and drain contact, and sections of the organic semiconductor that are doped with the irreversibly fixed dopant and have an increased electrical conductivity are disposed between the gate electrode and the source contact and/or between the gate electrode and the drain contact.

The source and drain contacts are, preferably, formed as sheet-like layers. Because, in this case, there is no overlap between the contacts and the gate electrode, there exist in the organic semiconductor regions between source contact and drain contact that are not influenced by the field of the gate electrode. However, because the regions that are disposed between source contact and gate electrode or drain contact and gate electrode, when viewed from above, are doped with the dopant, they have a conductivity that is increased by several powers of ten compared to that section of the organic semiconductor that is disposed on the gate electrode. Therefore, operation of the transistor is not impaired by these regions, but, rather, is in fact improved thereby.

In principle, suitable materials for the gate electrode and the source and drain contacts are all metals, preferably palladium, gold, platinum, nickel, copper, aluminum, and electrically conductive oxides (e.g., ruthenium oxide and indium tin oxide), and also electrically conductive polymers, such as polyacetylene or polyaniline.

The substrate used is, preferably, an inexpensive, flexible polymer film based on polyethylene naphthalate, polyethylene terephthalate, polyethylene, poly-propylene, polystyrene, epoxy resins, polyimides, polybenzoxazoles, polyethers and their variants that are provided with an electrically conductive coating, as well as flexible metal foils, glass, quartz or glasses provided with an electrically conductive coating.

The transistor described above can be fabricated at low cost and with a high yield, it being possible, in particular, for flexible polymer films to be used as substrate. This opens up a wide range of possible applications, for example, in active matrix displays or for transponders.

Other features that are considered as characteristic for the invention are set forth in the appended claims.

Although the invention is illustrated and described herein as embodied in a self-aligned contact doping for organic field-effect transistors and method for fabricating the transistor, it is, nevertheless, not intended to be limited to the details shown because various modifications and structural changes may be made therein without departing from the spirit of the invention and within the scope and range of equivalents of the claims.

The construction and method of operation of the invention, however, together with additional objects and advantages thereof, will be best understood from the following description of specific embodiments when read in connection with the accompanying drawings.

### BRIEF DESCRIPTION OF THE DRAWINGS

FIG. 1A is a fragmentary, cross-sectional view through a structure of an organic field-effect transistor according to the invention;

FIG. 1B is a fragmentary, cross-sectional view through a structure of an organic field-effect transistor according to the invention;

FIG. 1C is a fragmentary, cross-sectional view through a structure of an organic field-effect transistor according to the invention;

FIG. 2 is a fragmentary, cross-sectional view through a transistor according to the invention; and

FIG. 3 is a fragmentary, cross-sectional view of an illustration explaining the self-aligned back surface exposure for the doping of contact regions of the transistor of FIG. 2.

### DESCRIPTION OF THE PREFERRED EMBODIMENTS

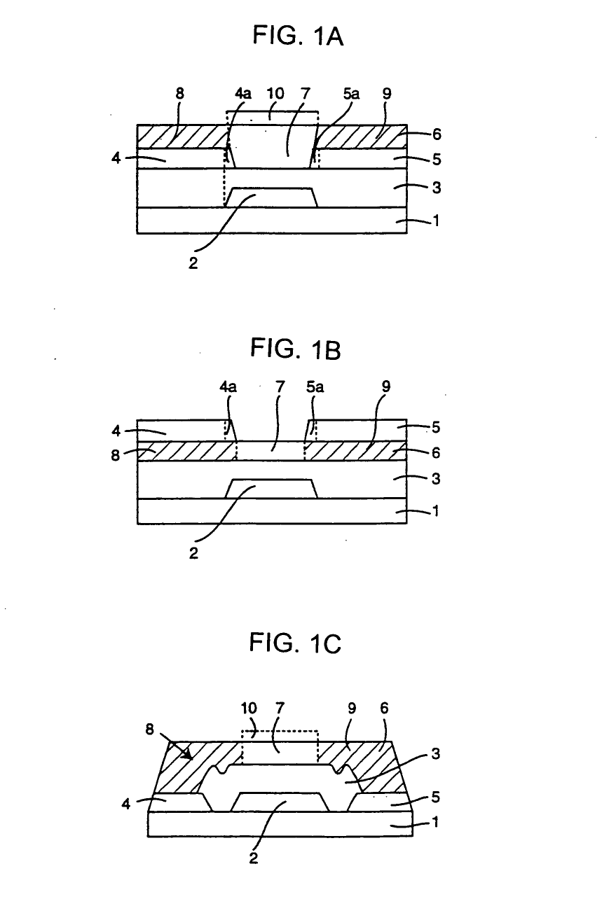

Referring now to the figures of the drawings in detail and first, particularly to FIGS. 1A, 1B, and 1C thereof, there is shown structures as have, hitherto, been used for organic transistors, these transistors having been modified according to the invention. The structure of the organic transistors that are illustrated in FIG. 1A and 1B requires four deposition and patterning steps, while the structure shown in FIG. 1C requires only three deposition steps.

For the fabrication of the transistor illustrated in FIG. 1A, first of all, a metal layer is deposited on a substrate 1 and is patterned to obtain the gate electrode 2. The substrate 1 is, for example, of glass or quartz and may also be fabricated from an organic polymer to be able to achieve higher flexibility of the configuration. The gate electrode 2 can be patterned using standard methods, for example, by photolithography, wet-chemical etching, plasma etching, printing, or lifting off. The gate electrode 2 is, then, insulated by applying a gate dielectric 4 to the gate electrode 2 and the substrate 1 surrounding it. Finally, a source contact 4 and a drain contact 5 are applied to the gate dielectric 3 and patterned. The contacts usually are of metal or electrically conductive polymers. The source contact 4 and the drain contact 5 are disposed such that, when the transistor is viewed from above, regions 4a and 5a in which the contacts overlap the gate electrode 2 are formed. Finally, a layer 6 of an organic semiconductor is deposited, the distance between source contact 4 and drain contact 5 being filled by the organic semiconductor 6. This region, which is disposed between the contacts 4 and 5 above the gate electrode 2, forms the channel region 7, in which the field of the gate electrode 2 influences the conductivity of the organic semiconductor 6. In this region, therefore, the organic semiconductor 6 must have a low electrical conductivity. In the contact regions 8 and 9, which are disposed above the source contact 4 and drain contact 5, the semiconductor is doped with a dopant. These regions, therefore, have a high electrical conductivity, which facilitates the transfer of charge carriers from the source contact 4 into the layer of the organic semiconductor 6 and from the layer of the organic semiconductor 6 into the drain contact 5. To enable a different conductivity to be realized in the different sections of the organic semiconductor 6, the organic semiconductor 6 is covered with a light-impermeable photomask 10 in the region of the channel. The photo-mask 10 can be applied and patterned using standard methods. In particular, it is also possible to use conventional chromium-on-glass masks or chromium-on-quartz masks, as are customarily employed in semiconductor technology for photolithography. Then, a dopant is introduced into the organic semiconductor 6, and the transistor is exposed from the side of the organic semiconductor 6, which in the context of the invention is referred to as the front surface, using activation radiation, for example, UV radiation. In the process, the dopant is excited and is fixed irreversibly in the organic semiconductor 6 by a chemical reaction in the exposed regions. Then, the photomask 10 is removed and unreacted dopant is removed again from the channel region 7 at elevated temperature or reduced pressure. Therefore, the original, low electrical conductivity of the organic semiconductor 6 is restored in the channel region 7.

FIG. 1B shows a similar structure to the transistor illustrated in FIG. 1A, except that the source contact 4 and the drain contact 5 are disposed above the organic semiconductor 6. As has already been described for the structure illustrated in FIG. 1A, first of all, a gate electrode 2 is deposited on a substrate 1 and is insulated using a gate dielectric 3. Then, a layer of an organic semiconductor 6 is deposited on the dielectric 3. The layer of the organic semiconductor 6 includes contact regions 8, 9, in which the electrical conductivity of the organic semiconductor 6 is increased with the aid of a dopant. In the channel region 7, the organic semiconductor 6 is not doped and, therefore, has a low electrical conductivity. To make it possible to form regions of different electrical conductivity in the organic semiconductor 6, first of all, a non-illustrated photomask is applied to the layer of the organic semiconductor 6 and is patterned, this photomask covering the region of the contact 7. Then, as described above, a dopant is introduced into the layer of the organic semiconductor 6 and is fixed in the organic semiconductor 6 by exposure using a suitable radiation, e.g., UV radiation, fixing taking place only in the exposed regions. Then, unreacted dopant is removed again from the organic semiconductor 6 at elevated temperature and reduced pressure. Next, a source contact 4 and a drain contact 5 are applied to the layer of the modified organic semiconductor 6, these contacts covering those regions of the organic semiconductor 6 that have previously been doped with the dopant. The contacts 4 and 5 are disposed such that, when viewed from above, they overlap the gate electrode 2 in the overlap regions 4a, 5a. As a result, the electrical conductivity in the channel region 7, which has a low electrical conductivity, is influenced by the field of the gate electrode 2, while the doped regions 8, 9 that have a high electrical conductivity are substantially uninfluenced by the field of the gate electrode. Finally, the photomask is removed again from the layer of the organic semiconductor 6 and, if appropriate, in a further step, unbonded dopant that is still present in the channel region 7 is removed at elevated temperature and/or lowered pressure.

The method for fabrication of the configuration of the components of the field-effect transistor shown in FIG. 1B can be simplified further if the substrate 1 and the gate dielectric 3 are of a material that is transparent to the activation radiation. The regions that are to be doped are, then, exposed by irradiation of the back surface of the configuration using the activation radiation, i.e., from the side that is formed by the substrate 1. The gate electrode 2, then, shields the region of the channel 7 from the activation radiation so that the semiconductor is not doped in this region. The gate electrode 2, then, has a self-aligning effect. It is, therefore, possible to dispense with the use of a mask.

FIG. 1C shows a transistor structure, the fabrication of which requires only three deposition steps. During fabrication, first of all, a gate electrode 2 and a source contact 4 and a drain contact 5 are deposited simultaneously on a substrate 1 and patterned. In such a case, source contact 4 or drain contact 5 and gate electrode 2 are disposed spaced apart from one another on the substrate 1 and, generally, are of the same material, for example, a metal or an electrically conductive polymer. Then, a gate dielectric 3 is deposited on the gate electrode 2. To insulate the latter, the distances between source contact 4 and gate electrode 2 and between drain contact 5 and gate electrode 2 are filled up by the gate dielectric 3. In a further deposition step, a layer of an organic semiconductor 6 is deposited on the configuration so produced. In the configuration illustrated in FIG. 1C, source contact 4, drain contact 5, and gate electrode 2 are disposed in one level. As a result, regions that are not influenced by the field of the gate electrode are formed in the layer of the semiconductor 6 between source contact 4 and drain contact 5. Therefore, in these regions, the electrical conductivity of the organic semiconductor 6 does not rise even when a voltage is applied to the gate electrode 2. To compensate for such a drawback, the regions of the organic semiconductor 6 that are not influenced by the field of the gate electrode 2 are doped with a dopant to increase the electrical conductivity. For such a purpose, first of all, the channel region 7, in which the low conductivity of the organic semiconductor is to be retained, is covered by a photomask 10. Then, the dopant is introduced into the organic semiconductor 6, and the configuration is exposed from the front surface, i.e., the side of the organic semiconductor layer 6, for the dopant to be fixed irreversibly in the organic semiconductor 6. As a result, regions 8, 9 that are in contact with the source contact 4 and the drain contact 5 and have an increased electrical conductivity are obtained. Then, the photomask 10 is removed again and unbonded dopant is removed again from the organic semiconductor 6 at elevated temperature and/or reduced pressure so that, in the channel region 7, the organic semiconductor is restored to its original, low electrical conductivity. Consequently, the regions 8 and 9 that are not influenced by the field of the gate electrode 2 are no longer of importance during the switching operations of the organic transistor on account of their increased electrical conductivity.

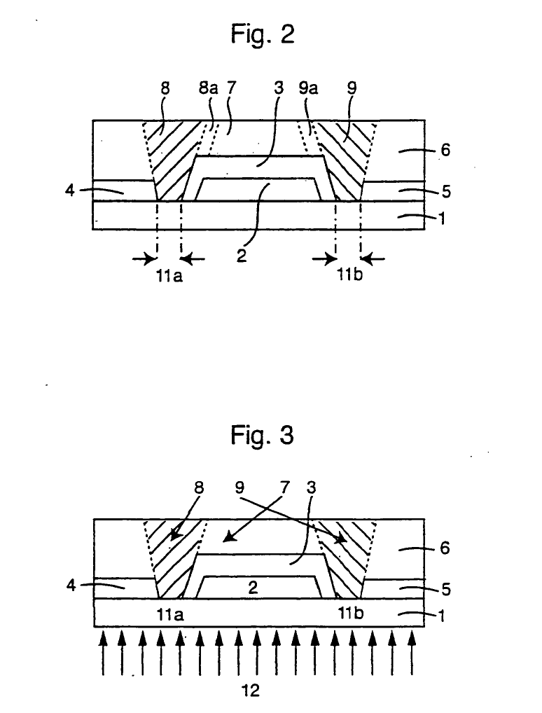

A particularly advantageous embodiment of the organic transistor according to the invention is illustrated in FIG. 2. Once again, a source contact 4, a gate electrode 2, and a drain contact 5 are disposed next to and at a distance from one another on a substrate 1. Source and drain contacts 4, 5 and gate electrode 2, in this case, preferably are of the same material. The gate electrode 2 is insulated by a gate dielectric 3. The configuration is selected to be such that a distance 11a is retained between the gate dielectric 3 and the source contact 4 and a distance 11b is retained between the gate dielectric 3 and the drain contact 5, at which the organic semiconductor 6 is applied directly to the substrate 1. A layer of the organic semiconductor 6 is applied to the configuration formed from source contact 4, drain contact 5, gate dielectric 3, and the substrate 1. This layer includes regions 8, 9 in which a dopant is fixed irreversibly in the organic semiconductor 6 so that the electrical conductivity of the latter is considerably increased. In the channel region 7, which is influenced by the field of the gate electrode 2, there is no dopant fixed in the organic semiconductor 6 and, consequently, the organic semiconductor 6 has a low electrical conductivity in this region.

The fabrication of the organic transistor shown in FIG. 2 is explained with reference to FIG. 3.

After the surface of the substrate 1, which may, for example, be of glass or a polymer film, has been cleaned, a layer of a suitable electrically conductive material, for example, palladium or gold, is applied and patterned, to define the gate electrode 2 and the source and drain contacts 4 and 5. The deposition of metal is effected, for example, by thermal vapor deposition, cathode sputtering, or printing. The patterning may be effected, for example, by photo-lithography, chemical etching, lifting off or printing. Then, the gate dielectric 3 is fabricated, for example, by depositing and patterning a layer of silicon dioxide or aluminum oxide or a suitable organic insulator. To obtain the layer of the organic semiconductor 6, an approximately 50 nm thick pentacene layer is, then, deposited by thermal sublimation from the vapor phase. All further work is carried out under yellow light. The substrate that has been so prepared is placed into a stainless-steel vessel fitted with a quartz window, and the vessel is evacuated. At a pressure of approximately 10 mbar, iron pentacarbonyl is passed over the substrate in a stream of nitrogen for 3 minutes. During this time, the iron pentacarbonyl diffuses into the organic semiconductor layer 6. The substrate is, then, polychromatically exposed from the back surface 12 through the quartz window using a mercury vapor lamp, for example, for 3 minutes at 15 mW/cm². The activation radiation emitted by the mercury vapor lamp activates the dopant iron pentacarbonyl and leads to a carbon monoxide ligand being eliminated. The coordinatively unsaturated iron compound is, then, coordinated at the organic semiconductor and, as a result, is fixed irreversibly. The gate electrode 2 shields the channel region 7 from the activation radiation so that the dopant is not fixed in this region. On account of the distances 11a, 11b, the activation radiation penetrates into the layer of the organic semiconductor 6, where it activates the dopant so that the dopant is fixed irreversibly in the organic semiconductor layer 6. After the exposure, unbonded dopant is removed, in the present example, by, firstly, stopping the supply of iron pentacarbonyl and, then, expelling iron pentacarbonyl that has not reacted in a stream of nitrogen at 10 mbar. Zones between source and gate and between gate and drain that are not controlled by the gate field are also present in the transistor structure illustrated in FIGS. 2 and 3. In these zones, the electric field applied to the gate electrode 2 has no influence on the charge carrier density in the semiconductor layer 6. However, the overlaps are not required because the semiconductor has a high electrical conductivity in the zones 8, 9 that are not influenced by the gate field. In such a case, it is sufficient if the gate electrode 2 influences only that part of the channel region 7 that is characterized by a low electrical conductivity.

The configuration shown in FIG. 2 can be improved still further if, in addition to the substrate 1, the gate dielectric 3 also is of a material that is transparent to the activation radiation. What material can be used for the gate dielectric 3 is dependent on the wavelength of the activation radiation, i.e., on the type of dopant and on the energy interplay between dopant and semiconductor. Silicon dioxide, for example, is transparent in the region of visible light and in the near UV, but is not transparent to UV radiation with wavelengths of below approximately 350 nm. Then, during the exposure of the configuration from the back surface 12, only the regions of the organic semiconductor 6 that are shielded from the activation radiation by the gate electrode 2 are not affected. The doped contact regions 8a and 9a seamlessly adjoin the region of the channel 7 that is influenced by the field of the gate electrode 2.

Only three material deposition and patterning processes are required for fabrication of the transistor structure illustrated in FIGS. 2 and 3. The proposed simplified transistor structure allows the contact regions to be exposed by a self-aligned back-surface exposure and, therefore, makes it possible to produce localized doping groups in the contact regions 8, 9 without increasing the electrical conductivity in the channel region 7 because this region is protected during the back-surface exposure by the light-impermeable gate electrode 2. Consequently, the fabrication costs of the transistor can be considerably reduced and the yield can be increased.

1. A method for doping electrically conductive organic compounds, which comprises:
introducing a doping substance activated by exposure with an activation radiation into an electrically conductive organic compound;
irreversibly fixing the activatable doping substance in the organic compound as a result of exposing the organic compound with the activation radiation; and
removing unbounded doping substance from the organic compound after the exposure.

2. The method according to claim 1, which further comprises carrying out the irreversible fixing of the doping substance by at least one of forming a covalent bond and forming a coordinate bond to the organic compound.

3. The method according to claim 1, which further comprises providing the organic compound as an organic semiconductor.

4. The method according to claim 1, which further comprises carrying out the exposure of the organic compound section by section.

5. The method according to claim 4, which further comprises carrying out the section by section exposure utilizing a photomask.

6. The method according to claim 1, which further comprises:
providing light-opaque regions opaque to the activation radiation used for the exposure in the organic compound; and
during the exposure, obtaining unexposed sections in the organic compound, the unexposed sections being disposed behind the light-opaque regions as seen in a direction of a radiation source used for the exposure to the organic compound.

7. The method according to claim 6, which further comprises forming the light-opaque regions by a gate electrode.

8. The method according to claim 6, which further comprises forming the light-opaque regions utilizing a gate electrode.

9. A method for fabricating an organic field-effect transistor, which comprises:
depositing a gate electrode, a source contact, a drain contact, a gate dielectric, and an electrically conductive organic semiconductor on a substrate;
introducing a doping substance activated by exposure with an activation radiation into the organic semiconductor;
carrying out section-by-section exposure with the activation radiation; and
after the exposure, removing unbounded doping substance from the organic semiconductor to irreversibly fix, in regions of the organic semiconductor adjoining the source contact and the drain contact, the doping substance in the organic semiconductor and to obtain contact regions adjoining the source contact and the drain contact, the contact regions having increased electrical conductivity.

10. The method according to claim 9, which further comprises applying a photomask for the section-by-section exposure.

11. The method according to claim 9, which further comprises carrying out the section-by-section exposure by applying a photomask.

12. The method according to claim 9, which further comprises:
providing the substrate as a substrate transparent to the activation radiation;
carrying out the depositing step by depositing, on the substrate, the source and drain contacts spaced apart from the gate electrode;
depositing a gate dielectric on the gate electrode to obtain a spacing in which the substrate is uncovered between the gate dielectric and the source contact and also between the gate dielectric and the drain contact;
depositing the organic semiconductor on the substrate, the source contact, the drain contact, and the gate dielectric to fill, with the organic semiconductor, at least one of the spacing between the gate dielectric and the source contact and the spacing between the gate dielectric and the drain contact;
carrying out the exposure step with the activation radiation from a side of the substrate to obtain, adjoining the source contact and the drain contact, contact regions having increased conductivity in the organic semiconductor; and
subsequently removing excess doping substance from the organic semiconductor.

13. The method according to claim 9, which further comprises simultaneously depositing the gate electrode, the source contact, and the drain contact on the substrate.

14. The method according to claim 9, which further comprises constructing the gate dielectric from a material transparent to the activation radiation.

15. The method according to claim 9, which further comprises providing the gate dielectric with a material transparent to the activation radiation.

16. An organic field-effect transistor, comprising:
a gate electrode;
a gate dielectric insulating said gate electrode;
a source contact;
a drain contact; and
an organic semiconductor:
being disposed between said source contact and said drain contact;
adjoining at least one of said source contact and said drain contact;
having a contact region with increased electrical conductivity; and
being doped with a doping substance irreversibly fixed in said organic semiconductor.

17. The organic field-effect transistor according to claim 16, further comprising:
a front side; and
a rear side having at least one section formed by said organic semiconductor.

18. The organic field-effect transistor according to claim 16, further comprising:
a front side; and
a rear side having said contact region formed by said organic semiconductor.

19. The organic field-effect transistor according to claim 17, wherein said rear side includes at least one section formed by one of said source contact and said drain contact, said at least one section adjoining said at least one section formed by said organic semiconductor.

20. The organic field-effect transistor according to claim 17, wherein said at least one section formed by said organic semiconductor is doped with said irreversibly fixed doping substance.

21. The organic field-effect transistor according to claim 16, wherein said doping substance is irreversibly fixed in said organic semiconductor by a covalent or a coordinate bond.

22. The organic field-effect transistor according to claim 16, wherein said doping substance has a covalent or a coordinate bond irreversibly fixing said doping substance in said organic semiconductor.

23. The organic field-effect transistor according to claim 16, wherein, in a plan view of the organic field-effect transistor, said gate electrode, said source contact, and said drain contact have no overlap and sections of said organic semiconductor doped with said irreversibly fixed doping substance and having an increased electrical conductivity are disposed at least one of between said gate electrode and said source contact and between said gate electrode and said drain contact.

24. The organic field-effect transistor according to claim 16, wherein:
in a plan view of the organic field-effect transistor, said gate electrode, said source contact, and said drain contact have no overlap; and
sections of said organic semiconductor doped with said irreversibly fixed doping substance and having an increased electrical conductivity are disposed at least one of between said gate electrode and said source contact and between said gate electrode and said drain contact.
